(19) United States
(12) Patent Application Publication
(10) Pub. No.: US 2022/0195119 A1
(43) Pub. Date: Jun. 23, 2022

(54) POLYAMIC ACID COMPOSITION FOR PRODUCING POLYIMIDE RESIN WITH SUPERIOR ADHESION AND POLYIMIDE RESIN PRODUCED THEREFROM

(71) Applicant: PI ADVANCED MATERIALS CO., LTD., Chungcheongbuk-do (KR)

(72) Inventors: Joo Young KIM, Sejong (KR); IK Sang Lee, Gyeongsangbuk-do (KR); Gyeong Hyeori Ro, Gyeongsangnam-do (KR)

(21) Appl. No.: 17/283,427

(22) PCT Filed: Nov. 20, 2018
(86) PCT No.: PCT/KR2018/014288

§ 371 Date: Apr. 7, 2021

(30) Foreign Application Priority Data
Oct. 11, 2018 (KR) 10-2018-0121185

(51) Int. Cl. C08G 73/10; C08J 5/18; H01L 23/29

(52) U.S. Cl. CPC C08G 73/1071; C08G 73/1042; C08J 2379/08; C08J 5/18; H01L 23/293; C08G 73/1032

(57) ABSTRACT

The present invention provides a polyamic acid composition comprising: a polyamic acid in which a dianhydride monomer comprising a first dianhydride having one benzene ring and a second dianhydride having a benzophenone structure, and a diamine monomer comprising a compound represented by Formula (1) are polymerized; and an organic solvent, wherein the mole ratio of the second dianhydride to the first dianhydride (the mole number of the second dianhydride/the mole number of the first dianhydride) is 0.2 to 1.2.

### TECHNICAL FIELD

The present invention relates to a polyamic acid composition for producing a polyimide resin having excellent adhesion and a polyimide resin prepared therefrom.

### BACKGROUND ART

Bonding between peripheral components constituting a circuit device such as a semiconductor is generally performed using a soldering method.

However, the linewidth of the circuit becomes finer and finer, and the lead used for soldering causes environmental problems, so that as a new bonding method that does not use lead is required, an adhesive that can withstand about 250° C. or more is required.

Therefore, polymer resins, which are less sensitive to environmental problems as compared to the lead, can be coated, applied, etc., and exhibit adhesion upon curing, tend to be used as adhesives for bonding the circuit, and a representative example of the polymer resin for bonding a circuit may include epoxies, acrylics, polyesters, polyimides, and the like.

Among them, epoxy, acrylic and polyester resins, and the like have excellent adhesion, and have an advantage in having a coefficient of thermal expansion suitable for bonding semiconductors including silicone-based materials, in detail, a coefficient of thermal expansion of 40 ppm/° C. to 50 ppm/° C., but have a fatal disadvantage of poor heat resistance. In addition, they are not very excellent in physical properties, such as resistance to chemicals, electrical insulation, chemical resistance and weather resistance, whereby there is a limit to being used universally as an adhesive.

Meanwhile, the polyimide resin is a polymer material, based on an imide ring having very excellent chemical stability together with a rigid aromatic main chain, that has the highest level of heat resistance, resistance to chemicals, electrical insulation, chemical resistance and weather resistance among polymer resins, which receives great attention as an adhesive for circuit bonding that strongly requires electrical reliability. Such a polyimide resin may be used as an adhesive by applying a polyamic acid-containing solution as a precursor to an object in the form of a thin film and then curing it by the action of heat and/or a chemical catalyst.

However, in general, the polyimide resin is difficult to be regarded as having high adhesion among polymer resins, and various studies have been conducted to further improve adhesion.

For example, in order to improve the adhesion of the polyimide resin, a method of limiting the content of the monomer has been attempted in some cases, but the adhesion is slightly improved, whereas mechanical properties such as an elongation and a tensile strength may be lowered, and dimensional stability, in detail, dimensional stability due to a coefficient of thermal expansion unsuitable for bonding of circuits such as semiconductors may be sacrificed.

Accordingly, there is a need for a novel polyimide resin capable of securing an appropriate level of glass transition temperature and dimensional stability while having better adhesion than the conventional one.

### DISCLOSURE

### Technical Problem

It is an object of the present invention to provide a novel polyimide resin capable of solving the above-recognized conventional problems at a stroke and a polyamic acid composition for preparing the polyimide resin.

According to one aspect of the present invention, a composition comprising a polyamic acid in which a dianhydride monomer comprising a first dianhydride having one benzene ring and a second dianhydride having a benzophenone structure, and a diamine monomer comprising a compound represented by Formula (1) according to the present invention are polymerized can implement a polyimide resin having excellent glass transition temperature and dimensional stability with the highest level of adhesion.

Accordingly, the present invention has a practical purpose to provide specific examples thereof.

### Technical Solution

In one embodiment, the present invention provides a polyamic acid composition comprising:

a polyamic acid in which a dianhydride monomer comprising a first dianhydride having one benzene ring and a second dianhydride having a benzophenone structure, and a diamine monomer comprising a compound represented by the following formula (1) are polymerized; and

an organic solvent.

wherein the mole ratio of the second dianhydride to the first dianhydride (=the mole number of the second dianhydride/the mole number of the first dianhydride) is 0.2 to 1.2:

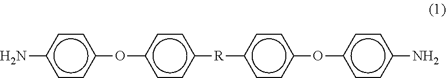

In Formula (1) above, R is —Cₙ₁(CH₃)₂ₙ₁—, —Cₙ₂(CF)₂ₙ₂—, —(CH₂)ₙ₃, or —O(CH₂)ₙ₄O—, and n1 to n4 are each independently an integer of 1 to 4.

In one embodiment, the present invention provides a polyimide resin prepared by imidizing the polyamic acid composition.

In one embodiment, the present invention provides a polyimide film made of the polyimide resin.

In one embodiment, the present invention provides an electronic component comprising the polyimide resin, wherein the electronic component may be a semiconductor that the polyimide resin is encapsulated in a bonded state.

Hereinafter, embodiments of the invention will be described in more detail in the order of the “polyamic acid composition” and “polyimide resin” according to the present invention.

Prior to this, the terms or words used in this specification and claims should not be construed as being limited to their usual or dictionary meanings, but should be interpreted as meanings and concepts consistent with the technical idea of the present invention based on the principle that the inventors can appropriately define the concept of terms in order to explain their own invention in the best way.

Therefore, the constitutions of the examples described in this specification are each only one of the most preferable examples of the present invention and do not represent all the technical idea of the present invention, so that it should be understood that various equivalents and modifications capable of replacing them at the time of the present application may exist.

In this specification, the singular expressions include plural expressions, unless the context clearly indicates otherwise. In this specification, the term such as “comprise,” “include” or “have” is intended to designate the presence of implemented features, numbers, steps, components or combinations thereof, but it should be understood that the presence or addition possibility of one or more other features or numbers, steps, components, or combinations thereof is not excluded in advance.

In this specification, the “dianhydride” is intended to include its precursors or derivatives, which may not be technically the dianhydride, but nevertheless, they will react with diamines to form polyamic acids, and these polyamic acids can be converted back to polyimides.

In this specification, the “diamine” is intended to include its precursors or derivatives, which may not be technically the diamine, but nevertheless, they will react with dianhydrides to form polyamic acids, and these polyamic acids can be converted back to polyimides.

When amounts, concentrations, or other values or parameters herein are given as enumeration of ranges, preferred ranges, or preferred upper limits and preferred lower limits, it should be understood to specifically disclose all ranges capable of being formed of any pair of any upper range limit or preferred value, and any lower range limit or preferred value, regardless of whether ranges are disclosed separately. When a range of numerical values is referred to herein, the range is intended to include the end-point value and all integers and fractions within the range, unless otherwise stated, for example, unless there is a limiting term such as more than or less than. It is intended that the scope of the invention is not limited to the specific values mentioned when defining the range.

Polyamic Acid Composition

The polyamic acid composition according to the present invention is

a polyamic acid composition for producing a polyimide resin,

which comprises a polyamic acid in which a dianhydride monomer comprising a first dianhydride having one benzene ring and a second dianhydride having a benzophenone structure, and a diamine monomer comprising a compound represented by the following formula (1) are polymerized; and

an organic solvent,

wherein the mole ratio of the second dianhydride to the first dianhydride (=the mole number of the second dianhydride/the mole number of the first dianhydride) may be 0.2 to 1.2.

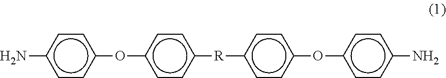

In Formula (1) above, R is —Cₙ₁(CH₃)₂ₙ₁—, —Cₙ₂(CF₃)₂ₙ₂—, —(CH₂)ₙ₃—, or —O(CH₂)ₙ₄O—, and n1 to n4 are each independently an integer of 1 to 4.

The polyamic acid composition according to the present invention allows the polyimide resin prepared therethrough to indwell the highest level of adhesion, excellent glass transition temperature and elongation, and an appropriate level coefficient of thermal expansion, specifically, a coefficient of thermal expansion of 40 ppm/° C. or more, whereby there are major features in solving the above-described conventional problems.

The specific constitutions of the polyamic acid composition according to the present invention and the significance of each constitution will be described through the following non-limiting examples.

In one specific example, the first dianhydride may be pyromellitic dianhydride (PMDA) having a relatively rigid molecular structure by having one benzene ring.

In order to improve the glass transition temperature of the polyimide resin, it may be advantageous to use a monomer having a rigid molecular structure, that is, a monomer having high linearity, and as the first dianhydride, the pyromellitic dianhydride may preferably act for the polyimide resin prepared from the polyamic acid composition of the present invention to have an appropriate level of glass transition temperature based on its rigid molecular structure and may also act advantageously in improving mechanical properties, such as a tensile strength, of the polyimide resin.

However, the pyromellitic dianhydride may not be a monomer that functions so that, for example, the polyimide resin has a desirable coefficient of thermal expansion and high elongation for bonding to a silicone-based substrate.

Therefore, in the polyimide resin prepared using only pyromellitic dianhydride as the first dianhydride, the coefficient of thermal expansion and elongation, and the glass transition temperature may be difficult to be compatible at appropriate levels.

However, surprisingly, when the second dianhydride having a benzophenone structure is used together with the first dianhydride pyromellitic dianhydride to implement a polyamic acid composition and a polyimide resin, physical properties related to dimensional stability, such as a coefficient of thermal expansion and an elongation, and the glass transition temperature, which are difficult to be compatible with each other, may be compatible at desirable levels.

In one specific example, the second dianhydride having the benzophenone structure may be 3,3′,4,4′-benzophenonetetracarboxylic dianhydride (BTDA).

As the benzophenone structure consists of a relatively flexible molecular structure, such a second dianhydride has a relatively flexible molecular structure with a benzophenone structure, such a second dianhydride may help improve the elongation of the polyimide resin and achieve an appropriate level of coefficient of thermal expansion, and has an advantage of excellent chemical resistance by itself.

The second dianhydride may also have a favorable effect on improving the adhesion of the polyimide resin prepared from the polyamic acid composition.

There are various causes why the adhesion of a typical polyimide resin does not reach a desired level, but it can be regarded as one cause that after forming a film of a polyamic acid composition on an object to be bonded, for example, a silicone-based substrate, a weak boundary layer (WBL) is formed at the contact interface with the object to be bonded. For reference, the weak boundary layer is in various forms, but one of them may be a form in which at least a portion of the polyimide resin at the contact interface is lifted without supporting the object to be bonded.

The lifted form may be caused, for example, by weak attractive force acting at the interface between the polyimide resin and the object to be bonded, or by moisture and/or an organic solvent, and the like that volatilize when a polyamic acid composition is converted to a polyimide resin.

The second dianhydride may improve the adhesion level of the polyimide resin through the interaction of the benzophenone structure with the hydrophilic group present in the object to be bonded.

In addition, the benzophenone structure of the second dianhydride may be advantageous that the volatilization of moisture and/or organic solvent is easily achieved at the initial point of conversion from the polyamic acid composition to the polyimide resin, and accordingly, the second dianhydride may advantageously act to suppress a phenomenon that the completely converted polyimide resin is lifted from the object to be bonded.

Consequently, the second dianhydride acts advantageously in minimizing the formation of such a weak boundary layer in the polyimide resin, whereby it may be related to the polyimide resin having the highest level of adhesion.

However, it is not preferable to use an excessive amount of the second dianhydride in consideration of only the above-described advantages, and the reason is because the decrease in the glass transition temperature due to a partial deficiency of the first dianhydride compared to the improvement of the elongation and adhesion of the polyimide resin can be quite large in the polyimide resin.

In one specific example of this, based on the total mole number of the dianhydride monomer, the content of the first dianhydride may be 40 mol % to 80 mol %, specifically 45 mol % to 70 mol %, and the content of the second dianhydride may be 20 mol % to 60 mol %, specifically 30 mol % to 55 mol %.

Also, in order that the polyimide resin has the highest level of adhesion while the dimensional stability-related physical properties and the glass transition temperature are compatible at desirable levels therein, it is especially important that the content of the first dianhydride and the second dianhydride is exquisitely balanced when preparing the polyamic acid composition.

Accordingly, the present invention provides a preferred mole ratio of the second dianhydride to the first dianhydride, where the mole ratio may be 0.2 to 1.2, more preferably 0.4 to 1, and particularly preferably 0.4 to 0.7.

When the mole ratio is below the above range, there is a problem that it leads to a decrease in the elongation and adhesion of the polyimide resin, whereas the glass transition temperature is hardly improved as compared to the case in the preferred range.

When the mole ratio exceeds the above range, it may act as a direct cause of a significant decrease in the glass transition temperature of the polyimide resin, and the adhesion and elongation may not be substantially improved as compared to the case in the preferred range.

Meanwhile, the diamine monomer comprising the compound represented by Formula (1) above may act advantageously for the polyimide resin prepared from the polyamic acid composition to have an improved elongation and an appropriate level of coefficient of thermal expansion, and may also act preferably to improve adhesion, based on a relatively flexible molecular structure.

In one specific example, R in Formula (1) above may be —C(CH₃)₂— or —C(CF₃)₂—, and more specifically, may be —C(CH₃)₂—.

In one specific example, the content of the compound of Formula (1) above may be 70 mol % to 100 mol % based on the total mole number of the diamine monomer.

That is, the compound of Formula (1) above may be used as a single component of the diamine monomer, and in some cases, the diamine monomer may also comprise other diamine components in a limited content together with the compound of Formula (1) for the purpose of improving other physical properties such as a tensile strength, a moisture absorption rate and resistance to bases.

When the compound of Formula (1) above is included below the above content range, it may cause a decrease in the elongation and adhesion of the polyimide resin prepared from the polyamic acid composition, so that it is preferably used within the range of the present invention.

Components that can be included in the diamine monomer as other diamine components together with the compound of Formula (1) above may be classified and exemplified as follows.

1) A diamine having a relatively rigid structure, as a diamine having one benzene ring in structure, such as 1,4-diaminobenzene (or paraphenylenediamine, PPD), 1,3-diaminobenzene, 2,4-diaminotoluene, 2,6-diaminotoluene and 3,5-diaminobenzoic acid (or DABA);

2) a diamine having two benzene rings in structure, such as diaminodiphenyl ether of 4,4′-diaminodiphenyl ether (or oxydianiline, ODA), 3,4′-diaminodiphenyl ether or the like, 4,4′-diaminodiphenylmethane (methylenediamine), 3,3′-dimethyl-4,4′-diaminobiphenyl, 2,2′-dimethyl-4,4′-diaminobiphenyl, 2,2′-bis(trifluoromethyl)-4,4′-diaminobiphenyl, 3,3′-dimethyl-4,4′-diaminodiphenylmethane, 3,3′-dicarboxy-4,4′-diaminodiphenylmethane, 3,3′,5,5′-tetramethyl-4,4′-diaminodiphenylmethane, bis(4-aminophenyl)sulfide, 4,4′-diaminobenzanilide, 3,3′-dichlorobenzidine, 3,3′-dimethylbenzidine (or o-tolidine), 2,2-dimethylbenzidine (or m-tolidine), 3,3′-dimethoxybenzidine, 2,2′-dimethoxybenzidine, 3,3′-diaminodiphenyl ether, 3,4′-diaminodiphenyl ether, 4,4′-diaminodiphenyl ether, 3,3′-diaminodiphenylsulfide, 3,4′-diaminodiphenylsulfide, 4,4′-diaminodiphenylsulfide, 3,3′-diaminodiphenylsulfone, 3,4′-diaminodiphenylsulfone, 4,4′-diaminodiphenylsulfone, 3,3-diaminobenzophenone, 4,4′-diaminobenzophenone, 3,3′-diamino-4,4′-dichlorobenzophenone, 3,3′-diamino-4,4′-dimethoxybenzophenone, 3,3′-diaminodiphenylmethane, 3,4′-diaminodiphenylmethane, 4,4′-diaminodiphenylmethane, 2,2-bis(3-aminophenyl)propane, 2,2-bis(4-aminophenyl)propane, 2,2-bis(3-aminophenyl)-1,1,1,3,3,3-hexafluoropropane, 2,2-bis(4-aminophenyl)-1,1,1,3,3,3-hexafluoropropane, 3,3′-diaminodiphenylsulfoxide and 3,4-diaminodiphenylsulfoxide, 4,4′-diaminodiphenylsulfoxide;

3) a diamine having three benzene rings in structure, such as 1,3-bis(3-aminophenyl)benzene, 1,3-bis(4-aminophenyl)benzene, 1,4-bis(3-aminophenyl)benzene, 1,4-bis(4-aminophenyl)benzene, 1,3-bis(4-aminophenoxy)benzene (or TPE-R), 1,4-bis(3-aminophenoxy)benzene (or TPE-Q) 1,3-bis(3-aminophenoxy)-4-trifluoromethylbenzene, 3,3′-diamino-4-(4-phenyl)phenoxybenzophenone, 3,3′-diamino-4,4′-di(4-phenylphenoxy)benzophenone, 1,3-bis(3-aminophenylsulfide)benzene, 1,3-bis(4-aminophenylsulfide)benzene, 1,4-bis(4-aminophenylsulfide)benzene, 1,3-bis(3-aminophenylsulfone)benzene, 1,3-bis(4-aminophenylsulfone)benzene, 1,4-bis(4-aminophenylsulfone)benzene, 1,3-bis[2-(4-aminophenyl)isopropyl]benzene, 1,4-bis[2-(3-aminophenyl)isopropyl]benzene and 1,4-bis[2-(4-aminophenyl)isopropyl]benzene; and

4) a diamine having four benzene rings in structure, such as 3,3′-bis(3-aminophenoxy)biphenyl, 3,3′-bis(4-aminophenoxy)biphenyl, 4,4′-bis(3-aminophenoxy)biphenyl, 4,4′-bis(4-aminophenoxy)biphenyl, bis[3-(3-aminophenoxy)phenyl]ether, bis[3-(4-aminophenoxy)phenyl] ether, bis[4-(3-aminophenoxy)phenyl] ether, bis[4-(4-aminophenoxy)phenyl] ether, bis[3-(3-aminophenoxy)phenyl]ketone, bis[3-(4-aminophenoxy)phenyl]ketone, bis[4-(3-aminophenoxy)phenyl]ketone, bis[4-(4-aminophenoxy)phenyl]ketone, bis[3-(3-aminophenoxy)phenyl]sulfide, bis[3-(4-aminophenoxy)phenyl]sulfide, bis[4-(3-aminophenoxy)phenyl]sulfide, bis[4-(4-aminophenoxy)phenyl]sulfide, bis[3-(3-aminophenoxy)phenyl]sulfone, bis[3-(4-aminophenoxy)phenyl]sulfone, bis[4-(3-aminophenoxy)phenyl]sulfone, bis[4-(4-aminophenoxy)phenyl]sulfone, bis[3-(3-aminophenoxy)phenyl]methane, bis[3-(4-aminophenoxy)phenyl]methane, bis[4-(3-aminophenoxy)phenyl]methane, bis[4-(4-aminophenoxy)phenyl]methane, 2,2-bis[3-(3-aminophenoxy)phenyl]propane, 2,2-bis[3-(4-aminophenoxy)phenyl]propane, 2,2-bis[4-(3-aminophenoxy)phenyl]propane, 2,2-bis[3-(3-aminophenoxy)phenyl]-1,1,1,3,3,3-hexafluoropropane, 2,2-bis[3-(4-aminophenoxy)phenyl]-1,1,1,3,3,3-hexafluoropropane, 2,2-bis[4-(3-aminophenoxy)phenyl]-1,1,1,3,3,3-hexafluoropropane and 2,2-bis[4-(4-aminophenoxy)phenyl]-1,1,1,3,3,3-hexafluoropropane.

A method for preparing the polyamic acid composition may include, for example,

(1) a method of putting the entire amount of a diamine monomer in an organic solvent, and then adding a dianhydride monomer so as to be substantially equimolar with the diamine monomer to polymerize them;

(2) a method of putting the entire amount of s dianhydride monomer in an organic solvent, and then adding s diamine monomer so as to be substantially equimolar with the dianhydride monomer to polymerize them:

(3) a method of putting some components of a diamine monomer in an organic solvent, followed by mixing some components of a dianhydride monomer therewith in a ratio of about 95 mol % to 105 mol % relative to the reaction components, and then adding the remaining diamine monomer components thereto and successively adding the remaining dianhydride monomer components thereto to polymerize the diamine monomer and the dianhydride monomer so that they are substantially equimolar to each other;

(4) a method of putting a dianhydride monomer in an organic solvent, followed by mixing some components of a diamine compound therewith in a ratio of 95 mol % to 105 mol relative to the reaction components, and then adding other dianhydride monomer components thereto and successively adding the remaining diamine monomer components thereto to polymerize the diamine monomer and the dianhydride monomer so that they are substantially equimolar to each other; and

(5) a method of reacting some diamine monomer components and some dianhydride monomer components so that any one is in an excessive amount in an organic solvent to form a first polymer, reacting some diamine monomer components and some dianhydride monomer components so that any one is in an excessive amount in another organic solvent to form a second polymer, and then mixing the first and second polymers and completing the polymerization, wherein when the diamine monomer components are in excess at the time of forming the first polymer, the dianhydride monomer components are in an excessive amount in the second polymer, and when the dianhydride monomer components are in excess in the first polymer, the diamine monomer components are in an excessive amount in the second polymer, thereby mixing the first and second polymers to polymerize the entire diamine monomer component and the entire dianhydride monomer component used in these reactions so that they are substantially equimolar to each other, and the like.

However, the above method is an example to aid in the implementation of the present invention, and the scope of the present invention is not limited thereto, and it goes without saying that any known method can be used.

The organic solvent is not particularly limited as long as it is a solvent in which the polyamic acid can be dissolved, but as one example, it may be an aprotic polar solvent.

A non-limiting example of the aprotic polar solvent may include an amide-based solvent such as N,N-dimethylformamide (DMF) and N,N′-dimethylacetamide (DMAc), and a phenolic solvent such as p-chlorophenol and o-chlorophenol, N-methyl-pyrrolidone (NMP), gamma-butyrolactone (GBL) and Diglyme, and the like, and these may be used alone or in combination of two or more.

In some cases, an auxiliary solvent such as toluene, tetrahydrofuran, acetone, methyl ethyl ketone, methanol, ethanol and water may also be used to adjust the solubility of the polyamic acid.

In one example, the organic solvent that can be particularly preferably used for preparing the precursor composition of the present invention may be N-methyl-pyrrolidone, N,N′-dimethylformamide and N,N′-dimethylacetamide.

The polyamic acid composition thus prepared may have a viscosity of 400 cP to 1,000 cP, specifically 500 cP to 700 cP, as measured at 23° C. when the solid content of the polyamic acid is 15%.

When the viscosity of the polyamic acid composition exceeds the above range, the dispenser nozzle used in the film forming process may be blocked by the polyamic acid composition, and when it is below the above range, a problem in the process may be caused, which is difficult to form a film with a desired thickness due to excessive fluidity of the polyamic acid composition. Besides, the low viscosity below the above range may lead to a decrease in adhesion of the polyimide resin formed by converting the polyamic acid composition.

In addition, even if the viscosity of the polyamic acid composition exceeds the above range, it is not preferable because it may be difficult to form a film in a desired form due to its high viscosity.

Meanwhile, the polyamic acid composition may further comprise at least one additive selected from acetic anhydride (AA), propionic acid anhydride, and lactic acid anhydride, quinoline, isoquinoline, β-picoline (BP) and pyridine.

When the polyamic acid composition is formed into a film and then converted into a polyimide resin, such an additive may help to obtain a desired polyimide resin by promoting a ring closure reaction through dehydrating action on the polyamic acid.

The additive may be included in an amount of 0.05 moles to 0.1 moles per 1 mole of the amic acid group in the polyamic acid.

If the additive is below the above range, the degree of acceleration of the dehydration and/or ring closure reaction is insufficient, and the polyamic acid composition may cause cracks in the converted polyimide resin and may cause a decrease in the strength of the polyimide resin.

In addition, if the additive amount of the additive exceeds the above range, imidization may proceed excessively quickly, and in this case, it is not preferable because it may be difficult to cast the polyamic acid composition in the form of a thin film or the converted polyimide resin may show brittle properties.

The polyamic acid composition may further comprise a filler for the purpose of improving various properties of the polyimide resin such as sliding properties, thermal conductivity, conductive properties, corona resistance and loop hardness of the polyimide resin derived from the polyamic acid composition.

The filler is not particularly limited, but a preferred example may include silica, titanium oxide, alumina, silicon nitride, boron nitride, calcium hydrogen phosphate, calcium phosphate, mica, and the like.

The average particle diameter of the filler is not particularly limited, which may be determined depending on the characteristics of the polyimide resin to be modified and the type of filler to be added. In one example, the average particle diameter of the filler may be 0.05 μm to 100 μm, specifically 0.1 μm to 75 μm, more preferably 0.1 μm to 50 μm, and particularly 0.1 μm to 25 μm.

If the average particle diameter is below this range, it becomes difficult to exhibit the modifying effect, and if it exceeds this range, the filler may greatly impair the surface property of the polyimide resin or cause a decrease in mechanical properties thereof.

In addition, the additive amount of the filler is not particularly limited, which may be determined by the properties of the polyimide resin to be modified or the particle diameter of the filler, and the like.

In one example, the amount of the filler added is 0.01 parts by weight to 100 parts by weight, preferably 0.01 parts by weight to 90 parts by weight, and more preferably 0.02 parts by weight to 80 parts by weight, relative to 100 parts by weight of the polyamic acid composition.

If the additive amount of the filler is below this range, it is difficult to show the modifying effect by the filler, and if it exceeds this range, the mechanical properties of the polyimide resin may be greatly deteriorated. The method of adding the filler is not particularly limited, and it goes without saying that any known method may be used.

Polyimide Resin

The polyimide resin according to the present invention may be prepared by imidizing the polyamic acid composition as described in the previous embodiments.

The polyimide resin of the present invention may have a glass transition temperature of 280° C. or more, specifically 280° C. to 350° C., and a coefficient of thermal expansion of 40 ppm/° C. or more, and specifically 40 ppm/° C. to 50 ppm/° C.

The glass transition temperature is a physical property representing the heat resistance of the polyimide resin, and for example, when the polyimide resin having the glass transition temperature is used as an adhesive, it can secure a high level of thermal stability to the object to be bonded, and the bonding process may be stably performed even at a high temperature of about 250° C. or more required for the bonding.

The coefficient of thermal expansion may belong to a range substantially similar to for example, the coefficient of thermal expansion of a silicon-based inorganic substrate, such as a semiconductor, and accordingly, the polyimide resin of the present invention replaces the circuit bonding by conventional soldering, whereby it can be preferably used as an adhesive for circuit bonding having excellent dimensional stability.

The polyimide resin of the present invention may also have a tensile strength of 140 MPa or more, thereby having excellent mechanical stiffness, and simultaneously may have an elongation of 100% or more, whereby flexibility also has an excellent advantage, and may be preferably used as an adhesive or electrical insulation material for flexible circuit parts which have been actively developed in recent years. In detail, the polyimide resin may have a tensile strength of 200 MPa or less and an elongation of 200% or less.

In the polyimide resin of the present invention, the area removed when measuring adhesion according to ASTM D 3359 on an inorganic substrate, for example, a silicon-based inorganic substrate, is also less than 5% of the total, specifically 3% or less, specifically 1% or less, whereby the polyimide resin may indwell the highest level of adhesion.

The method of measuring adhesion according to ASTM D 3359 may comprise steps of:

cutting the surface of a polyimide resin in a bonded state according to a cross cutter guide to form a grid pattern;

rubbing the surface of the polyimide resin using a brush or the like, and then attaching and removing a tape on the grid pattern; and

visually checking the gap pattern to calculate an area corresponding to the part removed due to the bonding release by the tape.

### DESCRIPTION OF DRAWING

FIG. 1 is a photograph that the polyimide resin of Example 1 is tested for adhesion and then the surface of the resin is photographed.

FIG. 2 is a photograph that the polyimide resin of Comparative Example 1 is tested for adhesion and then the surface of the resin is photographed.

FIG. 3 is a photograph that the polyimide resin of Comparative Example 5 is tested for adhesion and then the surface of the resin is photographed.

FIG. 4 is a photograph that the polyimide resin of Comparative Example 6 is tested for adhesion and then the surface of the resin is photographed.

### MODE FOR INVENTION

Hereinafter, the action and effect of the invention will be described in more detail through specific examples of the invention. However, these examples are merely illustrative of the invention, and the scope of the invention is not determined thereby.

### Example 1

To a 40° C. reactor filled with NMP, PMDA as the first dianhydride, BTDA as the second dianhydride and BAPP as the diamine were added in the mole ratio shown in Table 1 below, stirred for about 30 minutes to polymerize a polyamic acid and isoquinoline was introduced thereto in an amount of 0.05 to 0.1 moles per 1 mole of the amic acid group, and then the aging process was performed at 80° C. for about 2 hours to prepare a final polyamic acid composition.

### Example 2

A polyamic acid composition was prepared in the same manner as in Example 1, except that the polyamic acid was polymerized by changing PMDA as the first dianhydride and BTDA as the second dianhydride in the mole ratio shown in Table 1 below.

### Example 3

A polyamic acid composition was prepared in the same manner as in Example 1, except that the polyamic acid was polymerized by changing PMDA as the first dianhydride and BTDA as the second dianhydride in the mole ratio shown in Table 1 below.

### Comparative Example 1

A polyamic acid composition was prepared in the same manner as in Example 1, except that the polyamic acid was polymerized by changing PMDA as the first dianhydride and BTDA as the second dianhydride in the mole ratio shown in Table 1 below.

### Comparative Example 2

A polyamic acid composition was prepared in the same manner as in Example 1, except that the polyamic acid was polymerized by changing PMDA as the first dianhydride and BTDA as the second dianhydride in the mole ratio shown in Table 1 below.

### Comparative Example 3

A polyamic acid composition was prepared in the same manner as in Example 1, except that the polyamic acid was polymerized by changing PMDA as the first dianhydride and BTDA as the second dianhydride in the mole ratio shown in Table 1 below.

### Comparative Example 4

A polyamic acid composition was prepared in the same manner as in Example 1, except that the polyamic acid was polymerized by changing PMDA as the first dianhydride and BTDA as the second dianhydride in the mole ratio shown in Table 1 below.

### Comparative Example 5

As compared with Example 1, the first dianhydride was omitted, BTDA of the second dianhydride as the dianhydride monomer was used in a single component, and BAPP and ODA were used together as the diamine monomer.

Specifically, BTDA, BAPP as the first diamine and ODA as the second diamine were added in the mole ratio shown in Table 1 below to a 40° C. reactor filled with NMP, and stirred for about 30 minutes to polymerize a polyamic acid, and except for this, a polyamic acid composition was prepared in the same manner as in Example 1.

### Comparative Example 6

As compared with Example 1, the first dianhydride was omitted, BTDA of the second dianhydride as the dianhydride monomer was used as a single component, and ODA as the diamine monomer was used in a single component.

Specifically, BTDA and ODA were added in the mole ratio shown in Table 1 below to a 40° C. reactor filled with NMP, and stirred for about 30 minutes to polymerize a polyamic acid, and except for this, a polyamic acid composition was prepared in the same manner as in Example 1.

### Comparative Example 7

As compared with Example 1, the second dianhydride was omitted, and PMDA of the first dianhydride as the dianhydride monomer was used in a single component.

Specifically, PMDA and BAPP were added in the mole ratio shown in Table 1 below to a reactor at 40° C. filled with NMP, and stirred for about 30 minutes to polymerize a polyamic acid, and except for this, a polyamic acid composition was prepared in the same manner as in Example 1.

### Comparative Example 8

As compared with Example 1, the first dianhydride was omitted, and BPDA of the second dianhydride as the dianhydride monomer was used in a single component.

Specifically, BPDA and BAPP were added in the mole ratio shown in Table 1 below to a 40° C. reactor filled with NMP, and stirred for about 30 minutes to polymerize a polyamic acid, and except for this, a polyamic acid composition was prepared in the same manner as in Example 1.

### Comparative Example 9

As compared with Example 1, the first dianhydride was omitted, and only BTDA of the second dianhydride as the dianhydride monomer was used in a single component.

Specifically, BTDA and BAPP were added in the mole ratio shown in Table 1 below to a 40° C. reactor filled with NMP, and stirred for about 30 minutes to polymerize a polyamic acid, and except for this, a polyamic acid composition was prepared in the same manner as in Example 1.

### Comparative Example 10

As compared with Example 1, the first dianhydride was omitted BTDA of the second dianhydride as the dianhydride monomer was used in a single component, and BAPP and PPD were used together as the diamine monomer.

Specifically, BTDA. BAPP as the first diamine and PPD as the second diamine were added in the mole ratio shown in Table 1 below to a 40° C. reactor filled with NMP, and stirred for about 30 minutes to polymerize a polyamic acid, and except for this, a polyamic acid composition was prepared in the same manner as in Example 1.

### Comparative Example 11

A polyamic acid composition was prepared in the same manner as in Example 1, except that BPDA was used instead of BTDA as the second dianhydride, and the mole ratios of the first dianhydride and the second dianhydride were changed as shown in Table 1 below.

TABLE 1

| | | Composition | | | | Mole ratio | | | | Mole number of second |
|---|---|---|---|---|---|---|---|---|---|---|
| | | Dianhydride | | Diamine | | Dianhydride | | Diamine | | dianhydride/mole number |
| | | 1 | 2 | 1 | 2 | 1 | 2 | 1 | 2 | of first dianhydride |
| Example | 1 | PDMA | BTDA | BAPP | — | 50 | 50 | 100 | — | 1.00 |
| | 2 | PDMA | BTDA | BAPP | — | 70 | 30 | 100 | — | 0.42 |
| | 3 | PDMA | BTDA | BAPP | — | 60 | 40 | 100 | — | 0.67 |
| Comparative | 1 | PDMA | BTDA | BAPP | — | 90 | 10 | 100 | — | 0.11 |
| Example | 2 | PDMA | BTDA | BAPP | — | 75 | 25 | 100 | — | 0.33 |
| | 3 | PDMA | BTDA | BAPP | — | 30 | 70 | 100 | — | 2.33 |
| | 4 | PDMA | BTDA | BAPP | — | 43 | 57 | 100 | — | 1.32 |
| | 5 | — | BTDA | BAPP | ODA | — | 100 | 50 | 50 | — |
| | 6 | — | BTDA | — | ODA | — | 100 | — | 100 | — |
| | 7 | PMDA | — | BAPP | — | 100 | — | 100 | — | — |
| | 8 | — | BPDA | BAPP | — | — | 100 | 100 | — | — |
| | 9 | — | BTDA | BAPP | — | — | 100 | 100 | — | — |
| | 10 | — | BTDA | BAPP | PPD | — | 100 | 90 | 10 | — |
| | 11 | PMDA | BPDA | BAPP | — | 70 | 30 | 100 | — | 0.42 |

### Experimental Example 1: Physical Property Test of Polyimide Resin

The polyamic acid compositions prepared in Examples 1 to 3 and Comparative Examples 1 to 11 were each applied to a support in the form of a thin film and then imidized to prepare a polyimide resin in the form of a film having an average thickness of about 21 μm.

For the polyimide resin thus prepared, physical properties were tested in the following methods, and the results were shown in Table 2 below.

(1) Coefficient of Thermal Expansion (CTE)

The coefficient of thermal expansion was measured using TMA.

(2) Glass Transition Temperature (Tg)

As for the glass transition temperature, the loss elastic modulus and storage elastic modulus of each film were obtained using DMA, and the inflection point was measured as the glass transition temperature in their tangent graph.

(3) Tensile Strength

The tensile strength was measured by the method presented in KS6518.

(4) Elongation

The elongation was measured by the method presented in ASTM D1708.

TABLE 2

| | | Coefficient | Glass | | |
|---|---|---|---|---|---|
| | | of thermal | transition | Tensile | |
| | | expansion | temperature | strength | Elongation |
| | | (ppm/° C.) | (° C.) | (MPa) | (%) |
| Example | 1 | 49 | 282 | 141 | 106 |
| | 2 | 44 | 302 | 146 | 128 |
| | 3 | 45 | 297 | 145 | 115 |
| Comparative | 1 | 31 | 307 | 131 | 94 |
| Example | 2 | 38 | 304 | 146 | 112 |
| | 3 | 54 | 262 | 135 | 25 |
| | 4 | 49 | 271 | 136 | 19 |
| | 5 | 38 | 365 | 121 | 45 |
| | 6 | 43 | 277 | 128 | 25 |
| | 7 | 34 | 315 | 138 | 15 |
| | 8 | 58 | 257 | 132 | 75 |
| | 9 | 60 | 254 | 135 | 81 |
| | 10 | 42 | 281 | 132 | 21 |
| | 11 | 38 | 298 | 141 | 84 |

As shown in Table 2, the examples showed a very good elongation of 100% or more.

In addition, the examples have a glass transition temperature of 280° C. or more and a tensile strength of 140 MPa or more, thereby satisfying the compliant heat resistance and mechanical properties, and also satisfy a thermal expansion coefficient of 40 ppm/° C. to 50 ppm/° C. suitable for semiconductor bonding.

That is, it can be seen that in the examples carried out according to the present invention, the glass transition temperature, and the elongation and the predetermined coefficient of thermal expansion related to the dimensional stability, which are difficult to be compatible with each other, are compatible at desirable levels.

On the other hand, in Comparative Examples 1 to 4 that the content ratios of the first dianhydride and the second dianhydride were out of the scope of the present invention, most of the physical properties were poor as compared to the examples, and in particular, the glass transition temperature, and the physical properties related to the dimensional stability were not compatible.

Meanwhile, in Comparative Examples 5 to 11, the polyimide resins were prepared by using conventional polyamic acid compositions prepared using monomers different from the present invention, and as in Comparative Examples 1 to 4, most of the physical properties were poor as compared to the examples.

### Experimental Example 2: Adhesion Test of Polyimide Resin

The polyamic acid compositions prepared in Examples 1 to 3 and Comparative Examples 1 to 11 were each cast on a silicon-based inorganic substrate at 35 μm and dried at a temperature range of 50° C. to 350° C. to prepare a polyimide resin in the form of a film having an average thickness of about 21 μm.

For the polyimide resin thus prepared, the adhesion was measured using the method set forth in ASTM D 3359 below, and the results were shown in Table 3 below:

A step of cutting the surface of a polyimide resin in a bonded state according to a cross cutter guide to form a grid pattern;

a step of rubbing the surface of the polyimide resin using a brush or the like, and then attaching and removing a tape on the grid pattern; and

a step of visually checking the gap pattern to calculate an area corresponding to the part removed due to the bonding release by the tape.

TABLE 3

| | | Adhesion** |
|---|---|---|
| Example | 1 | 5B |
| | 2 | 5B |
| | 3 | 5B |
| Comparative | 1 | 2B |
| Example | 2 | 4B |
| | 3 | 3B |
| | 4 | 3B |
| | 5 | 3B |
| | 6 | 1B |
| | 7 | 0B |
| | 8 | 2B |
| | 9 | 5B |
| | 10 | 1B |
| | 11 | 3B |

**5B: smooth state substantially without any removed area; 4B: the removed area is about 5% of the total; 3B: the removed area is 5 to 15%; 2B: the removed area is 15 to 35%; 1B: the removed area is 35 to 65%; 0B: most have been removed.

In the examples, the smooth surface state was maintained without a part that the bonding was released by the tape, and the highest level of adhesion was shown among the grades according to ASTM D 3359.

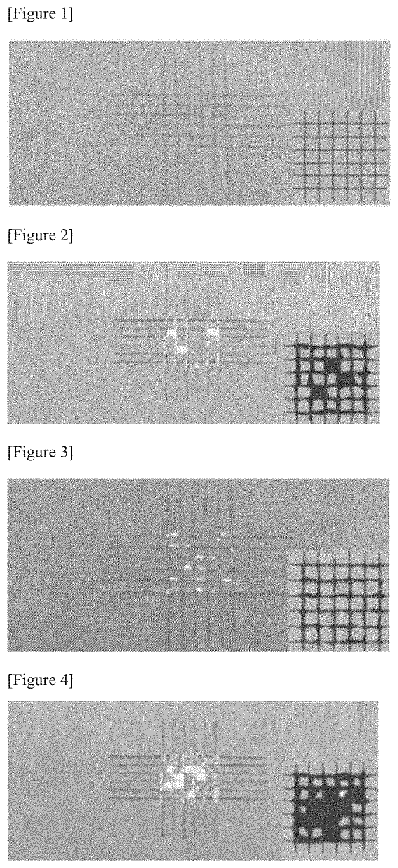

In response, FIG. 1 shows a photograph that the polyimide resin of Example 1 is tested for adhesion and then the surface of the resin is photographed (an enlarged photograph at the lower right).

Referring to FIG. 1, it can be confirmed that even though the tape has been attached to the grid pattern and removed therefrom, there is substantially no removed part due to the bonding release.

It can be expected therefrom that the polyamic acid compositions and the polyimide resins according to the embodiments of the present invention can be preferably used as an adhesive for circuit bonding, in detail, a semiconductor including a silicon-based inorganic substrate, out of the limit on the adhesion of the conventional polyimide resin.

On the other hand, Comparative Examples 1 to 4, in which the content ratio of the first dianhydride and the second dianhydride was out of the scope of the present invention, exhibited remarkably poor adhesion as compared to the examples.

In this regard, FIG. 2 shows a photograph that the polyimide resin of Comparative Example 1 is tested for adhesion and then the surface of the resin is photographed. Referring to FIG. 2, it can be confirmed from Comparative Example 1 that the area removed after bonding is remarkably wide.

Consequently, it can be understood from Comparative Examples 1 to 4 that when the content of the first dianhydride and the second dianhydride falls within the scope of the present invention and they are used in an optimal ratio, excellent adhesion is finally expressed.

Other Comparative Examples except Comparative Example 9 also showed poor adhesion as compared to the examples.

In this regard, FIG. 3 shows a photograph that the polyimide resin of Comparative Example 5 is tested for adhesion and then the surface of the resin is photographed, and FIG. 4 shows a photograph that the polyimide resin of Comparative Example 6 is tested for adhesion and then the surface of the resin is photographed.

Referring to these drawings, it can be seen from Comparative Example 5 and Comparative Example 6 that the area removed after bonding is wide, whereby there is a limit to being used as an adhesive.

Although the foregoing has been described with reference to the examples of the present invention, those having ordinary knowledge in the field to which the present invention belongs will be able to perform various applications and modifications within the scope of the present invention based on the above contents.

### INDUSTRIAL APPLICABILITY

As described above, the polyamic acid composition according to the present invention has an advantage in producing a polyimide resin that physical properties related to dimensional stability, such as a coefficient of thermal expansion and an elongation, and a glass transition temperature, which are difficult to be compatible with each other, can be compatible at desirable levels, and having the highest level of adhesion.

The present invention also provides a polyimide resin prepared from the polyamic acid composition, wherein the polyimide resin has the highest level of adhesion that an area removed when measuring adhesion according to ASTM D 3359 on an inorganic substrate is less than 5% of the total, and simultaneously has a glass transition temperature of 280° C. or more, a coefficient of thermal expansion of 40 ppm/° C. or more, a tensile strength of 140 MPa or more, and an elongation of 100% or more, which may indwell very excellent characteristics.

1. A polyamic acid composition for producing a polyimide resin,
comprising a polyamic acid in which a dianhydride monomer comprising a first dianhydride having one benzene ring and a second dianhydride having a benzophenone structure, and a diamine monomer comprising a compound represented by the following formula (1) are polymerized; and
an organic solvent,
wherein the mole ratio of the second dianhydride to the first dianhydride (=the mole number of the second dianhydride/the mole number of the first dianhydride) is 0.2 to 1.2. 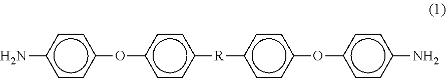
wherein, R is —Cₙ₁(CH₃)₂ₙ₁—, —Cₙ₂(CF₃)₂ₙ₂—, —(CH₂)ₙ₃—, or —O(CH₂)ₙ₄O—, and n1 to n4 are each independently an integer of 1 to 4.

2. The polyamic acid composition according to claim 1,
wherein the mole ratio of the second dianhydride to the first dianhydride is 0.4 to 1.

3. The polyamic acid composition according to claim 1,
wherein the content of the first dianhydride is 40 mol % to 80 mol % and the content of the second dianhydride is 20 mol % to 60 mol %, based on the total mole number of the dianhydride monomer.

4. The polyamic acid composition of claim 1,
wherein the first dianhydride is pyromellitic dianhydride (PMDA).

5. The polyamic acid composition of claim 1,
wherein the second dianhydride is 3,3′,4,4′-benzophenonetetracarboxylic dianhydride (BTDA).

6. The polyamic acid composition according to claim 1,
wherein the content of the compound of Formula (1) above is 70 mol % to 100 mol %, based on the total mole number of the diamine monomer.

7. The polyamic acid composition according to claim 1,
wherein R in Formula (1) above is —C(CH₃)₂— or —C(CF₃)₂—.

8. The polyamic acid composition according to claim 1,
wherein R in Formula (1) above is —C(CH₃)₂—.

9. The polyamic acid composition according to claim 1,
further comprising at least one additive selected from acetic anhydride (AA), propionic acid anhydride, and lactic acid anhydride, quinoline, isoquinoline, β-picoline (BP) and pyridine.

10. The polyamic acid composition according to claim 9,
wherein the additive is contained in an amount of 0.05 moles to 0.1 moles per 1 mole of the amic acid group in the polyamic acid.

11. The polyamic acid composition according to claim 1,
wherein when the solid content of the polyamic acid is 15%, the viscosity measured at 23° C. is 400 cP to 1,000 cP.

12. A polyimide resin prepared by imidizing the polyamic acid composition according to claim 1.

13. The polyimide resin according to claim 12,
wherein an area removed when measuring adhesion according to ASTM D 3359 on an inorganic substrate is less than 5% of the total.

14. The polyimide resin according to claim 12,
wherein the glass transition temperature is 280° C. or more,
and the coefficient of thermal expansion is 40 ppm/° C. or more.

15. The polyimide resin according to claim 12,
wherein the tensile strength is 140 MPa or more,
and the elongation is 100% or more.

16. A polyimide film made of the polyimide resin according to claim 12.

17. An electronic component comprising the polyimide resin according to claim 12.

18. The electronic component according to claim 17,
wherein the electronic component is a semiconductor that the polyimide resin is encapsulated in a bonded state.
